(19) United States
(12) Patent Application Publication
(10) Pub. No.: US 2015/0062915 A1
(43) Pub. Date: Mar. 5, 2015

(54) LIGHT EMITTING DIODE DEVICES AND METHODS WITH REFLECTIVE MATERIAL FOR INCREASED LIGHT OUTPUT

(71) Applicant: Cree, Inc., Durham, NC (US)

(72) Inventors: Christopher P. Hussell, Cary, NC (US); Jesse Colin Reiherzer, Wake Forest, NC (US); Erin R. F. Welch, Chapel Hill, NC (US); Florin A. Tudorica, Durham, NC (US)

(21) Appl. No.: 14/019,257

(22) Filed: Sep. 5, 2013

(51) Int. Cl. H01L 33/10; F21K 99/00; F21V 7/22

(52) U.S. Cl. CPC H01L 33/10; F21V 7/22; F21K 9/50
USPC 362/296.01; 438/27

(57) ABSTRACT

Light emitter devices and methods are provided herein. In some aspects, emitter devices and methods provided herein are for light emitting diode (LED) chips and can include providing a substrate, a conductive trace over the substrate, and at least one or more direct attach LED chip over the substrate. A layer of non-conductive and reflective material is disposed over the surface of wherein the layer of reflective material covers at least 25% or more of a surface of the substrate.

### TECHNICAL FIELD

The subject matter disclosed herein relates generally to light emitter devices and methods for light emitting diode (LED) chips. More particularly, the subject matter disclosed herein relates to light emitting diode devices and methods for increased light output.

### BACKGROUND

Light emitting diodes (LEDs) or LED chips are solid state devices that convert electrical energy into light. LED chips can be utilized in light emitter devices or components for providing different colors and patterns of light useful in various lighting and optoelectronic applications. Manufacturers of LED lighting products are constantly seeking ways to maintain and/or increase brightness levels while using the same or less power.

Conventional research efforts to increase lumen output and optical efficiency from LED chips are focused on novel device structures and/or materials, which can lead to LED devices that are expensive and time consuming to fabricate.

Accordingly, and despite the availability of various light emitter devices and components in the marketplace, a need remains for brighter and more efficient light emitter devices and methods that can be produced quickly and at a lower cost. Such devices can also make it easier for end-users to justify switching to LED products from a return on investment or payback perspective.

### SUMMARY

In accordance with this disclosure, light emitter devices and related methods for light emitting diode (LED) chips are provided. Light emitter devices and methods described herein can advantageously exhibit improved brightness and ease of manufacture. Such devices can also be provided at lower processing costs. Light emitter devices and related methods described herein can be well suited for a variety of applications such as personal, industrial, and commercial lighting applications including, for example, light bulbs and light fixture products and/or applications. It is, therefore, an object of the present disclosure to provide chip on board (COB) light emitter devices and methods having integrally formed lenses that are sized and/or shaped to provide brighter and more efficient LED products.

According to one aspect, the subject matter described herein can comprise a light emitter device that includes a substrate, at least one direct attach light emitting diode (LED) chip disposed over the substrate's surface, an electrically conductive pad disposed over the substrate surface, and a layer of reflective material disposed over the substrate, where the layer of reflective material outside of the conductive trace covers at least 25% or more of the substrate surface.

These and other objects of the present disclosure as can become apparent from the disclosure herein are achieved, at least in whole or in part, by the subject matter disclosed herein.

### BRIEF DESCRIPTION OF THE DRAWINGS

A full and enabling disclosure of the present subject matter including the best mode thereof to one of ordinary skill in the art is set forth more particularly in the remainder of the specification, including reference to the accompanying figures, in which:

FIG. 1A is a top perspective view of one embodiment of a light emitter device according to the disclosure herein;

FIG. 1B is a top perspective view of another embodiment of a light emitter device according to the disclosure herein;

FIGS. 2 to 3E are top plan views of one embodiment of a light emitter device according to the disclosure herein;

FIGS. 4 to 5C are cross-section views of a light emitter device according to the disclosure herein;

FIGS. 6A to 6D are cross-section views of a light emitter device according to the disclosure herein;

FIG. 7 is a flow chart of a method for providing a light emitter device according to the disclosure herein;

FIGS. 8A to 8C are a top view, a side view, and a bottom view, respectively, of a light emitting diode chip according to the disclosure herein;

FIG. 9 is a side view of a light emitting diode chip according to the disclosure herein; and

FIG. 10 is a side view of a light emitting diode chip according to the disclosure herein.

### DETAILED DESCRIPTION

The subject matter disclosed herein is directed to light emitter devices and related methods for use with light emitting diode (LED) chips. In some aspects, emitter devices and related methods can be substrate based devices having chip on board (COB) LED chips, where the LED chips can be batch processed. Devices and methods provided herein can exhibit improved manufacturability as well increased light emission at a lower cost.

Reference will be made in detail to possible aspects or embodiments of the subject matter herein, one or more examples of which are shown in the figures. Each example is provided to explain the subject matter and not as a limitation. In fact, features illustrated or described as part of one embodiment can be used in another embodiment to yield still a further embodiment. It is intended that the subject matter disclosed and envisioned herein covers such modifications and variations.

As illustrated in the various figures, some sizes of structures or portions are exaggerated relative to other structures or portions for illustrative purposes and, thus, are provided to illustrate the general structures of the present subject matter. Furthermore, various aspects of the present subject matter are described with reference to a structure or a portion being formed on other structures, portions, or both. As will be appreciated by those of skill in the art, references to a structure being formed “on” or “above” another structure or portion contemplates that additional structure, portion, or both may intervene. References to a structure or a portion being formed “on” another structure or portion without an intervening structure or portion are described herein as being formed “directly on” the structure or portion. Similarly, it will be understood that when an element is referred to as being “connected”, “attached”, or “coupled” to another element, it can be directly connected, attached, or coupled to the other element, or intervening elements may be present. In contrast, when an element is referred to as being “directly connected”, “directly attached”, or “directly coupled” to another element, no intervening elements are present.

Furthermore, relative terms such as “on”, “above”, “upper”, “top”, “lower”, or “bottom” are used herein to describe one structure's or portion's relationship to another structure or portion as illustrated in the figures. It will be understood that relative terms such as “on”, “above”, “upper”, “top”, “lower” or “bottom” are intended to encompass different orientations of the device in addition to the orientation depicted in the figures. For example, if the device in the figures is turned over, structure or portion described as “above” other structures or portions would now be oriented “below” the other structures or portions. Likewise, if devices or components in the figures are rotated along an axis, structure or portion described as “above”, other structures or portions would be oriented “next to” or “left of” the other structures or portions. Like numbers refer to like elements throughout.

As used herein, the terms “batch processing” or processing as a “batch” refer to performing a particular operation on a group of devices and/or LED chips at a same processing step and/or all at once, rather than manually performing the particular operation on each device or chip, one at a time and individually.

Unless the absence of one or more elements is specifically recited, the terms “comprising”, including”, and “having” as used herein should be interpreted as open-ended terms that do not preclude the presence of one or more elements.

Light emitter packages according to embodiments described herein can comprise group III-V nitride (e.g., gallium nitride (GaN)) based LED chips or lasers. Fabrication of LED chips and lasers is generally known and only briefly described herein. LED chips or lasers can be fabricated on a growth substrate, for example, a silicon carbide (SiC) substrate, such as those devices manufactured and sold by Cree, Inc. of Durham, N.C. Other growth substrates are also contemplated herein, for example and not limited to sapphire, silicon (Si), and GaN. In one aspect, SiC substrates/layers can be 4H polytype silicon carbide substrates/layers. Other SiC candidate polytypes, such as 3C, 6H, and 15R polytypes, however, can be used. Appropriate SiC substrates are available from Cree, Inc., of Durham, N.C., the assignee of the present subject matter, and the methods for producing such substrates are set forth in the scientific literature as well as in a number of commonly assigned U.S. patents, including but not limited to U.S. Pat. No. Re. 34,861; U.S. Pat. No. 4,946,547; and U.S. Pat. No. 5,200,022, the disclosures of which are incorporated by reference herein in their entireties. Any other suitable growth substrates are contemplated herein.

As used herein, the term “Group III nitride” refers to those semiconducting compounds formed between nitrogen and one or more elements in Group III of the periodic table, usually aluminum (Al), gallium (Ga), and indium (In). The term also refers to binary, ternary, and quaternary compounds such as GaN, AlGaN and AlInGaN. The Group III elements can combine with nitrogen to form binary (e.g., GaN), ternary (e.g., AlGaN), and quaternary (e.g., AlInGaN) compounds. These compounds may have empirical formulas in which one mole of nitrogen is combined with a total of one mole of the Group III elements. Accordingly, formulas such as AlxGa1-xN where 1>x>0 are often used to describe these compounds. Techniques for epitaxial growth of Group III nitrides have become reasonably well developed and reported in the appropriate scientific literature.

Although various embodiments of LED chips disclosed herein can comprise a growth substrate, it will be understood by those skilled in the art that the crystalline epitaxial growth substrate on which the epitaxial layers comprising an LED chip are grown can be removed, and the freestanding epitaxial layers can be mounted on a substitute carrier substrate or substrate which can have different thermal, electrical, structural and/or optical characteristics than the original substrate. The subject matter described herein is not limited to structures having crystalline epitaxial growth substrates and can be used in connection with structures in which the epitaxial layers have been removed from their original growth substrates and bonded to substitute carrier substrates.

Group III nitride based LED chips according to some embodiments of the present subject matter, for example, can be fabricated on growth substrates (e.g., Si, SiC, or sapphire substrates) to provide horizontal devices (with at least two electrical contacts on a same side of the LED chip) or vertical devices (with electrical contacts on opposing sides of the LED chip). Moreover, the growth substrate can be maintained on the LED chip after fabrication or removed (e.g., by etching, grinding, polishing, etc.). The growth substrate can be removed, for example, to reduce a thickness of the resulting LED chip and/or to reduce a forward voltage through a vertical LED chip. A horizontal device (with or without the growth substrate), for example, can be flip chip bonded (e.g., using solder) to a carrier substrate or printed circuit board (PCB), or wirebonded. A vertical device (with or without the growth substrate) can have a first terminal (e.g., anode or cathode) solder bonded to a carrier substrate, mounting pad, or PCB and a second terminal (e.g., the opposing anode or cathode) wirebonded to the carrier substrate, electrical element, or PCB. Examples of vertical and horizontal LED chip structures are discussed by way of example in U.S. Publication No. 2008/0258130 to Bergmann et al. and in U.S. Pat. No. 7,791,061 to Edmond et al. which issued on Sep. 7, 2010, the disclosures of which are hereby incorporated by reference herein in their entireties.

As used herein, “direct attach” as used to describe an LED chip or chips includes, without limitation, an LED chip and attachment method as described for example in U.S. Publication Nos. 2012/0193649 and 2012/0193662, both filed on Aug. 2, 2012 and commonly owned herewith, the contents of both of which are incorporated by reference in their entireties herein.

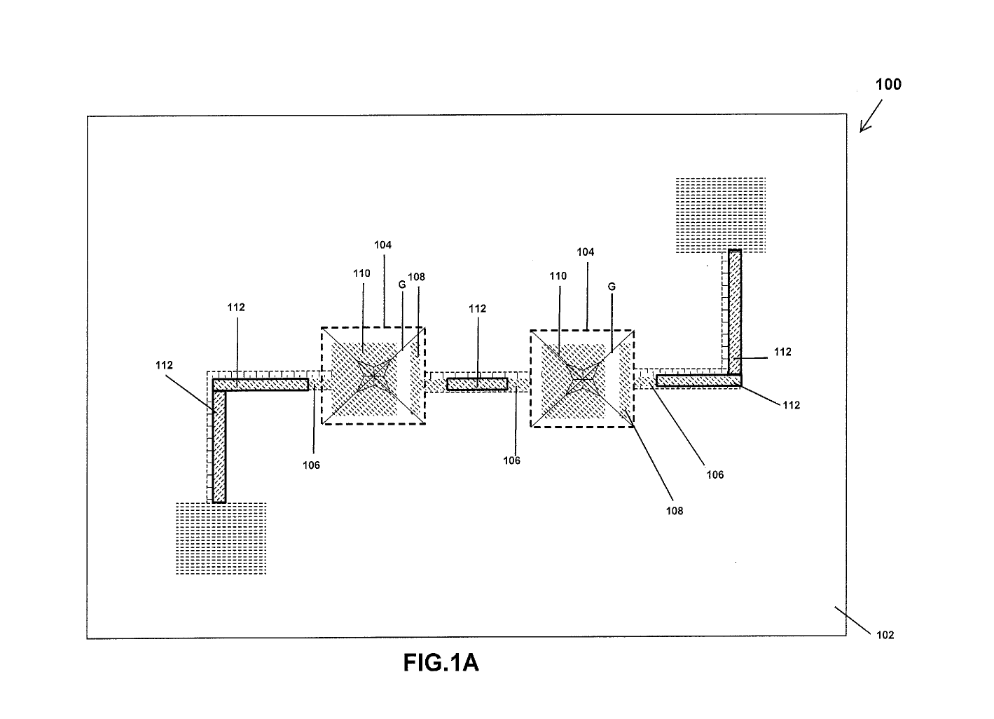

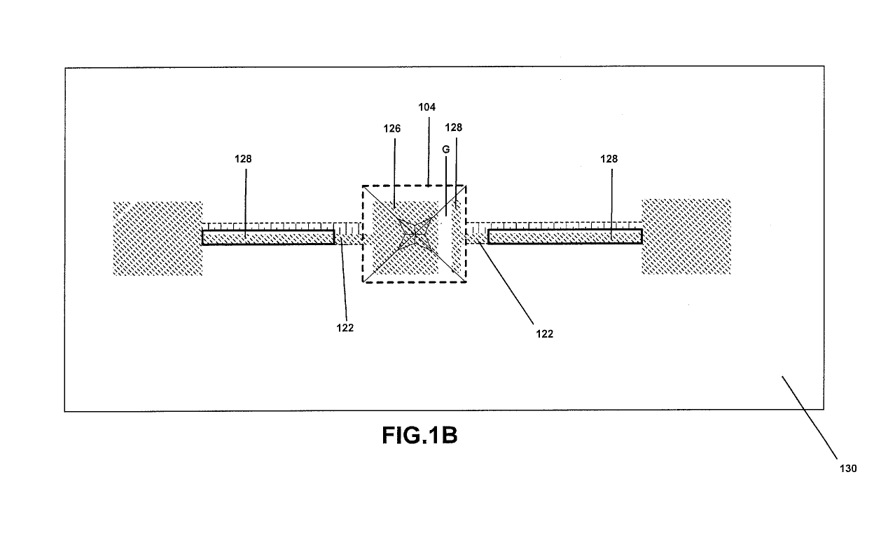

FIG. 1A of the drawings illustrates a top view of a light emitter device, generally designated 100. Light emitter device 100 can comprise a substrate 102 over which at least two light emitting diode (LED) devices 104 can be disposed. The substrate 102 can comprise any suitable mounting substrate, for example, a semiconductor wafer, a printed circuit board (PCB), a metal core printed circuit board (MCPCB), an external circuit, or any other suitable substrate over which lighting devices such as LEDs may mount and/or attach. In some aspects, it may be preferred to utilize aluminum nitride (AlN) or aluminum oxide (Al₂O₃) substrates for their high isolation voltages and excellent heat dissipating capabilities.

In some aspects, the light emitter device 100 can comprise conductive traces 106 and pads 108 and 110 configured to provide electrical bias to LED chips 104. The traces 106 and pads 108, 110 can comprise any suitable electrically conductive material known in the art, for example, metal or metal alloys, copper (Cu), aluminum (Al), tin (Sn), silver (Ag), conductive polymer material(s), and/or combinations thereof. In some aspects, the conductive traces 106 can be disposed in a position lower than the conductive pads 108, 110.

In some aspects, conductive traces 106 and pads 108, 110 can comprise copper (Cu) deposited using known techniques such as plating. In one aspect, a titanium adhesion layer and copper seed layer can be sequentially sputtered onto substrate 102, then approximately 75 μm of Cu can be plated onto the Cu seed layer. The resulting Cu layer being deposited can then be patterned using standard lithographic processes. In other embodiments the Cu layer can be sputtered using a mask to form the desired pattern of pads 108 and 110 such that the mask is used to from a gap, generally designated G, by preventing deposition of Cu in that area. In some aspects, the gap G can physically separate the pads 108 and 110 so the pads are electrically isolated from each other. Gap G can extend down to the top surface of the substrate 102 thereby electrically isolating conductive pads 108 and 110. In one aspect, gap G can provide electrical isolation between the conductive pads 108 and 110 to prevent shorting of the electrical signal applied to LED chip 104.

In some aspects, conductive traces 106 and pads 108, 110 can be plated or coated with additional metals or materials to make pads 108, 110 more suitable for mounting LED chips 104 and/or to improve optical properties, such as amount of light emitted by device 100. For example, conductive traces 106 and pads 108, 110 can be plated with adhesive materials, bonding materials, and/or barrier materials or layers. In one aspect, conductive traces 106 and pads 108, 110 can be plated with any suitable thickness of nickel (Ni) barrier layer and a reflective silver (Ag) layer disposed over the Ni barrier for increasing reflection from device 100.

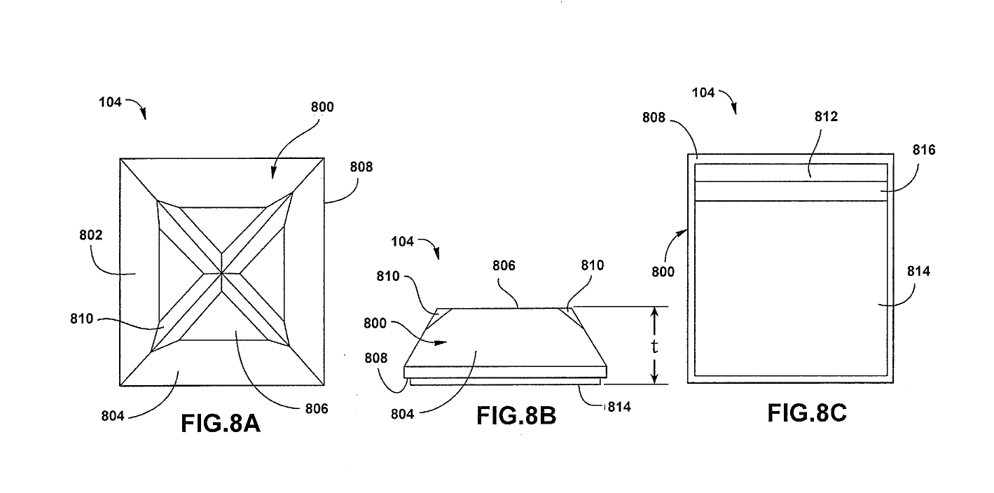

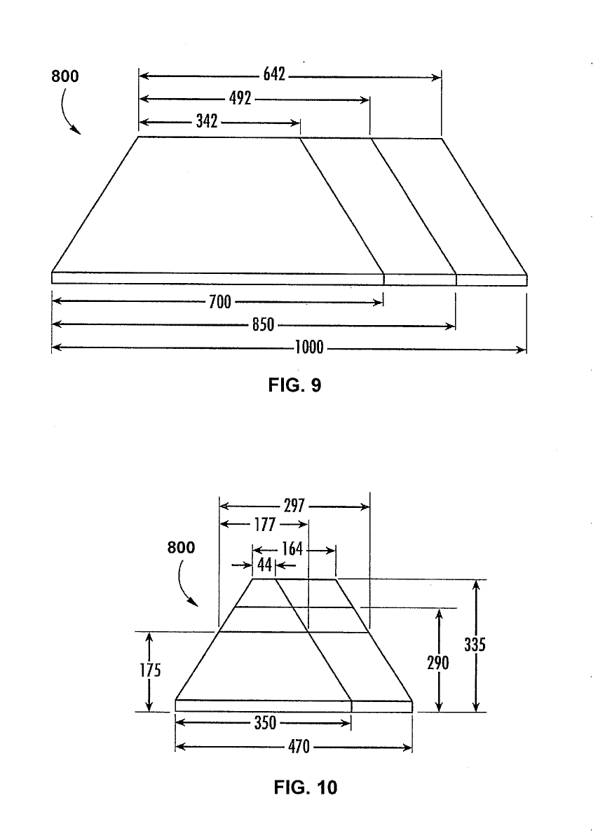

In some aspects, for example and without limitation, the LED devices 104 can be or comprise any of the embodiments depicted by FIGS. 8A to 10. LED chip 104 can comprise a substrate, generally designated 800, that is beveled cut, thereby providing a chip having angled or beveled surfaces disposed between an upper face and a lower face. Specifically, FIGS. 8A to 8C illustrate an embodiment where the LED chip 104 is a substantially square shaped chip where adjacent surfaces 802 and 804 can comprise substantially the same length. For example and without limitation, the LED chip 104 can be a square shaped chip, such as a CREE DA 500 chip commercially available with adjacent surface lengths of 500 μm each. However, FIG. 10 illustrates an embodiment where the substrate of LED chip 104 can comprise a substantially rectangular shaped chip where adjacent surfaces 802 and 804 are different lengths. For example, the chip can be a CREE DA 250 LED chip and can have one adjacent surface length at 250 μm and the other one at a longer length. As illustrated in FIG. 9, some embodiments of the LED chip 104 can have adjacent sides 802 and 804 of approximately 1 mm in length (e.g., 1000 μm) or less in at least one direction. In other aspects, each of the adjacent sides 802 and 804 can comprise approximately 0.85 mm (e.g., 850 μm) in length or less in at least two directions, such as approximately 0.70 mm (e.g., 700 μm), 0.50 mm (e.g., 500 μm), 0.40 mm (e.g., 400 μm), and 0.30 mm (e.g., 300 μm) or less. LED chip 104 can comprise a thickness t of approximately 0.40 mm or less (e.g., 400 μm or less) such as 0.34 mm (e.g., 340 μm) or less. In one aspect and as illustrated in FIG. 8B, LED chip 104 can comprise a thickness t of approximately 0.335 mm (e.g., 335 μm) or various sub-ranges of thicknesses t from 0.15 to 0.34 mm, such as: approximately 0.15 to 0.17 mm (e.g., 150 to 170 μm); 0.17 to 0.2 mm (e.g., 170 to 200 μm); 0.2 to 0.25 mm (e.g., 200 to 250 μm); 0.25 to 0.30 mm (e.g., 250 to 300 μm); and 0.30 to 0.34 mm (300 to 340 μm).

In some aspects, some LED chip 104 can be approximately 4 mm² or less in total surface area, other can be 2 mm² or less in total surface area. In some aspects, LED chip 104 can comprise an area (e.g., product of the lengths of adjacent sides 52 and 54) of approximately 0.74 mm² or less, for example, 0.72 mm² or less. In other aspects, LED chips 104 can be various sub-ranges of surface area from approximately 0.25 to 0.72 mm², for example, such as: approximately 0.25 to 0.31 mm²; 0.31 to 0.36 mm²; 0.36 to 0.43 mm²; 0.43 to 0.49 mm²; 0.49 to 0.56 mm²; 0.56 to 0.64 mm²; and 0.64 to 0.72 mm². In one aspect, an upper face 806 can comprise a smaller surface area than a lower face 808. One or more beveled or angled sides, such as adjacent surfaces 802 and 804 can be disposed between upper and lower faces 806 and 808, respectively. At least one groove, such as an X-shaped groove 810 can be disposed in upper face 86 of LED chip 104. Multiple X-shaped grooves and/or other shaped grooves can also be provided. In one aspect, grooves 60 can improve light extraction.

As illustrated by FIG. 8C, LED chip 104 can comprise electrical contacts on the same surface, for example, bottom face 808. Electrical contacts can comprise an anode conductive pad 812 and a cathode conductive pad 814 which can collectively occupy less area than diode's active region. Anode 812 can be at least partially disposed over and electrically communicate with the conductive pad 108. Cathode 814 can be at least partially disposed over and electrically communicate with conductive pad 110 as shown in FIG. 1A. A gap 816 can be disposed between anode 812 and cathode 814. In one aspect, gap 816 can for example be approximately 75 μm or less. After die attachment of LED chip 104 to conductive pads 108 and 110, gap 816 can be at least partially disposed over gap G of device 104. Alternatively, in some aspects, a LED device can comprise anode 812 and cathode 814 contacts of similar sizes.

In one aspect, LED chip 104 can comprise a direct attach type of chip that is horizontally structured such that electrically connecting chip to electrical components wire bonding is not required. That is, LED chip 104 can comprise a horizontally structured device where each electrical contact (e.g., the anode and cathode) can be disposed on the bottom surface of LED chip 104. Die attaching LED chip 104 using any suitable material and/or technique (e.g., solder attachment, preform attachment, flux or no-flux eutectic attachment, silicone epoxy attachment, metal epoxy attachment, thermal compression attachment, and/or combinations thereof) can directly electrically connect LED chip 104 to conductive pads 108 and 110 as indicated in FIG. 1A without requiring wire bonds.

In some aspects, LED chip 104 can be a device that does not comprise angled or beveled surfaces. For example, chip 104 can be any LED device that comprises coplanar electrical contacts on one side of the LED (bottom side) with the majority of the light emitting surface being located on the opposite side (upper side).

FIGS. 9 and 10 illustrate various measurements of LED chip substrate 800. FIG. 9 illustrates various dimensions for square adjacent sides 802 and 804. FIG. 10 illustrates various dimensions for rectangular chips where adjacent sides 802 and 804 are different, for example, where side 802 is smaller than side 804. FIG. 10 illustrates various dimensions of the smaller and larger sides 802 and 804 of LED chip substrate 800 thickness. In one aspect, adjacent sides 802 and 804 can comprise approximately 350 μm×470 μm and can comprise a thickness, or height, of approximately 175 μm or greater. In other aspects, substrate thickness 800 can have a height of approximately 290 μm or greater. In further aspects, substrate thickness 800 can have a height of approximately 335 μm or greater (e.g., 0.335 mm). In one aspect, upper face 806 can be a rectangle of approximately 177 μm×297 μm in length and width. In other aspects, upper face can be a rectangle of approximately 44 μm×164 μm in length and width. Such LED chips 104 can have a ratio between area of upper face 806 and area of adjacent sides 802 and 804 of approximately 0.4 or less. It has been found that the light extraction and output is improved as the ratio of the area of upper face 806 to the area of sides 802 and 804 is reduced.

Referring back to FIG. 1A, LED chips 104 can be electrically connected via conductive traces 106 disposed over the substrate 102. In some aspects, each LED chip 104 can connected via at least one trace 106 and conductive pads 108 and 110. For example, the anode and cathode conductive pads can be bonded to traces or other structures on or associated with the LED chips. In some aspects, traces 106 can comprise an electrically conductive materiel, for example, a metal such as copper (Cu), aluminum (Al), tin (Sn), silver (Ag), gold (Au), alloys thereof, or any other suitable material adapted to pass electrical current into and out of LED chips 104. Traces 106 can be physically or chemically deposited, plated, stenciled, or otherwise provided over portions of substrate 102. Traces can be provided between adjacent rows of LED chips 104, such that the chips can be serially connected and/or connected in parallel therebetween. Combinations of serially connected and parallel connected LED chips 104 can be provided over substrate 102. In some aspects, the conductive traces 106 can be narrower in width than the conductive pads 108, 110 and/or the LED chip 104. For example and without limitation, the LED chip 104 can be a CREE DA 500 chip with a width of 500 μm, and the conductive trace 106 can have a width from approximately 50 to 100 μm. A narrow conductive trace means that there is less metal on substrate 102, which advantageously improves light output from light emitter device 100 by reducing light absorption by the metal. Similarly, conductive pads 108, 110 can be smaller in overall surface area and dimensions compared to the LED chip 104. For example and without limitations, the LED chip 104 can be a CREE 500 LED with a surface area size of 500 μm×500 μm or 250,000 μm², and the conductive pads 108, 110 can have an overall dimensions that are at 90% or lower of a DA 500 LED chip. In one aspect, for example, a width of conductive trace 106 can be 30% or less of a width of the LED chip 104.

In some aspects, the light emitter device 100 can have a layer of reflective material disposed over the substrate 102 surface. For example, a layer of electrically non-conductive reflective material, such as in the form of a solder mask layer, can be disposed over the exposed regions of the substrate surface including the gap G regions (e.g. part of the substrate surface absent traces, conductive pads, or other device structures). The electrically non-conductive reflective layer, or any other suitable material adapted to facilitate reflection of light generated by the LED chips 104, can be utilized to increase the overall light output of the light emitter device 100. In some aspects, the electrically non-conductive reflective layer can be disposed on at least 25% or more of the surface of substrate 102 outside of the conductive trace or traces such as traces 106 and at a height equal to or lower, or even higher than a height of the conductive traces 106 and pads 108, 110. The reflective material can be applied in one step as one layer if desired and can in some aspects also cover at least a portion of the conductive traces without covering the LED chip(s). Furthermore, in some aspects, the conductive traces 106, conductive pads 108, 110, and other metal components of light emitter device 100 can be coated with a reflective Ag layer for increasing light reflection. An additional electrically non-conductive reflective layer, such as a second solder mask layer 112, can be deposited to cover the reflective Ag layer. The additional electrically non-conductive reflective layer 112 reduces Ag corrosion due to phosphorus, light absorption due to metals, and increase light reflection.

FIG. 1B illustrates a top view of another embodiment of a light emitter device, generally designated 120. Light emitter device 120 can comprise a substrate 130 over which at least one light emitter diode (LED) device 104 can be disposed. The substrate 130 can comprise any suitable mounting substrate, for example, a semiconductor wafer, a printed circuit board (PCB), a metal core printed circuit board (MCPCB), a ceramic substrate, an external circuit, or any other suitable substrate over which lighting devices such as LEDs may mount and/or attach. In some aspects, it can be preferable to utilize aluminum nitride (AlN) or aluminum oxide (Al2O3) substrates for their high isolation voltages and excellent heat dissipating capabilities.

In some aspects, the light emitter device 120 can comprise conductive traces 122 and pads 124 and 126 configured to provide electrical bias to LED chips 104. The traces 122 and pads 124, 126 can comprise any suitable electrically conductive material known in the art, for example, metal or metal alloys, copper (Cu), aluminum (Al), tin (Sn), silver (Ag), conductive polymer material(s), and/or combinations thereof.

In some aspects, conductive traces 122 and pads 124, 126 can comprise copper (Cu) deposited using known techniques such as plating. In one aspect, a titanium adhesion layer and copper seed layer can be sequentially sputtered onto substrate 130, then approximately 75 μm of Cu can be plated onto the Cu seed layer. The resulting Cu layer being deposited can then be patterned using standard lithographic processes. In other embodiments the Cu layer can be sputtered using a mask to form the desired pattern of pads 124 and 126 such that the mask is used to from a gap, generally designated G, by preventing deposition of Cu in that area. In some aspects, the gap G can physically separate the pads 124 and 126 so the pads are electrically isolated from each other. Gap G can extend down to the top surface of the substrate 130 thereby electrically isolating conductive pads 124 and 126. In one aspect, gap G can provide electrical isolation between the conductive pads 124 and 126 to prevent shorting of the electrical signal applied to LED chip 104.

In some aspects, conductive traces 122 and pads 124, 126 can be plated or coated with additional metals or materials to make pads 124, 126 more suitable for mounting LED chips 104 and/or to improve optical properties, such as amount of light emitted by device 120. For example, conductive traces 122 and pads 124, 126 can be plated with adhesive materials, bonding materials, and/or barrier materials or layers. In one aspect, conductive traces 122 and pads 124, 126 can be plated with any suitable thickness of nickel (Ni) barrier layer and a reflective silver (Ag) layer disposed over the Ni barrier for increasing reflection from device 130.

In some aspects, for example and without limitation, the LED devices 104 can be or comprise any of the embodiments depicted by FIGS. 8A to 10. LED chip 104 can comprise a substrate, generally designated 800, that is beveled cut, thereby providing a chip having angled or beveled surfaces disposed between an upper face and a lower face. Alternatively, in some aspects, LED chip 104 can be a device that does not comprise angled or beveled surfaces. For example, chip 104 can be any LED device that comprises coplanar electrical contacts on one side of the Led (bottom side) with the majority of the light emitting surface being located on the opposite side (upper side).

In some aspects, the light emitter device 120 can have a layer of reflective material disposed over the substrate 130 surface. For example, the reflective material can be an electrically non-conductive material such as solder mask, and it can be disposed over the exposed regions of the substrate surface including the gap G regions (e.g. part of the substrate surface absent traces, conductive pads, or other device structures). The electrically non-conductive reflective layer, or any other suitable material adapted to facilitate reflection of light generated by the LED chips 104, can be utilized to increase the overall light output of the light emitter device 120. In some aspects, the reflective material outside of the conductive traces 122 can be disposed on at least 25% or more of the surface of substrate 130 surface and at a height equal to or lower, or even higher than a height of the conductive traces 122 and pads 124, 126. The reflective material can be applied in one step as one layer if desired and can in some aspects also cover at least a portion of the conductive traces without covering the LED chip(s). Furthermore, in some aspects, the conductive traces 122, conductive pads 124, 126, and other metal components of light emitter device 120 can be coated with a reflective Ag layer for increasing light reflection. An additional reflective layer, such as a second electrically non-conductive reflective layer 128, can be deposited to cover the reflective Ag layer. The additional reflective layer 128 reduces Ag corrosion due to phosphorus, light absorption due to metals, and increase light reflection.

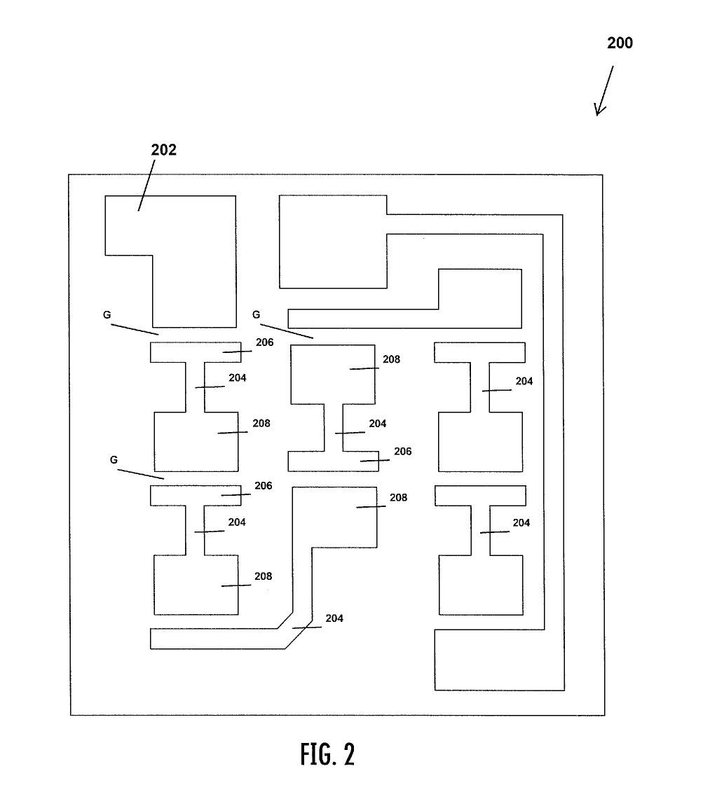

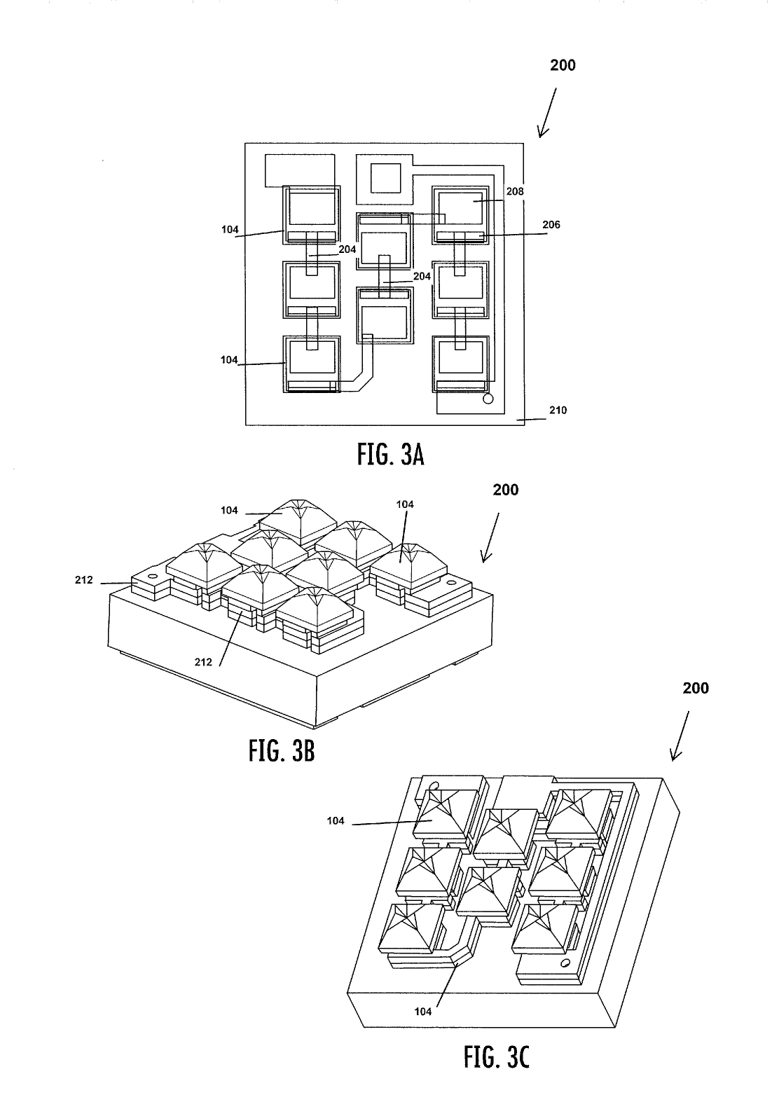

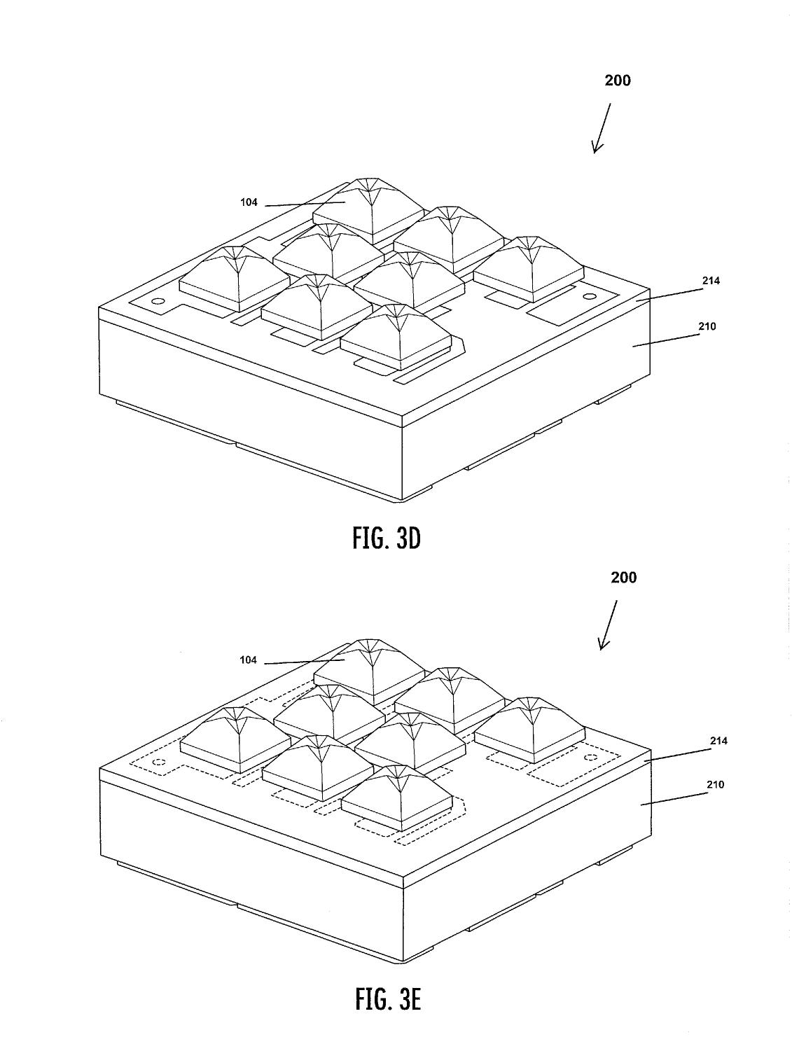

FIGS. 2 to 3E illustrate another embodiment of a light emitter device, generally designated 200. FIG. 2 depicts an electric circuitry 202 including a plurality of conductive traces 204 and pads 206, 208 configured to mount eight direct attach LED chips 104 in series. It should be noted that the circuit set up as shown in FIG. 2 is provided to explain the subject matter and not as a limitation.

In some aspects, conductive traces 204 and pads 206, 208 can comprise copper (Cu) deposited using any suitable or known technique such as plating. In one aspect, a titanium adhesion layer and copper seed layer can be sequentially sputtered onto substrate 210, then Cu, for example approximately 75 μm of Cu, can be plated onto the Cu seed layer. The resulting Cu layer being deposited can be patterned using standard lithographic processes. In other embodiments the Cu layer can be sputtered using a mask to form the desired pattern of pads 206 and 208 such that the mask is used to from a gap, generally designated G, by preventing deposition of Cu in that area. In some aspects, the gap G can physically separate the pads 206 and 208 so the pads are electrically isolated from each other. Furthermore, in some aspects, the conductive traces 106 can be disposed in a position lower than the conductive pads 108, 110.

In some embodiments, the conductive traces 204 can be narrower in width than the conductive pads 206, 28 and/or the LED chip. For example and without limitation, the LED chip can be a CREE DA 500 chip with a width of 500 μm, and the conductive trace 204 can have a width from approximately 50 to 100 μm. A narrow conductive trace means that there is less metal on substrate 210, which improves and increases light output and brightness from light emitter device 200 by reducing light absorption by the metal. Similarly, conductive pads 206, 208 can be smaller in overall surface area and dimensions compared to the LED chip. For example and without limitation, the LED chip can be a CREE 500 LED with a surface area size of 500 μm×500 μm or 250,000 μm², and the conductive pads 206, 208 can have overall dimensions that are at 90% or lower of a DA 500 LED chip.

Referring to FIGS. 3A to 3E, light emitter device 200 can for example include eight direct attach LED chips 104 mounted on a plurality of conductive pads 206, 208 and connected in series by conductive traces 204. As illustrated in FIG. 3A, each LED chip 104 can be connected via at least one trace 204 and conductive pads 206 and 208. For example, a cathode conductive pad 208 of a first LED chip can be electrically coupled to an anode conductive pad 206 of a second LED chip via at least one conductive trace. Furthermore, conductive pads 206 and 208 can be electrically isolated from each other by a gap G. Gap G can extend down to the top surface of the substrate 210 thereby electrically isolating conductive pads 206 and 208. In one aspect, gap G can provide electrical isolation between the conductive pads 206 and 208 to prevent shorting of the electrical signal applied to LED chip 104.

In some aspects, the light emitter device 200 can have a layer of reflective material disposed over the substrate 210 surface. For example, a layer of electrically non-conductive reflective material such as solder mask can be disposed over the exposed regions of the substrate surface including the gap G regions (e.g. part of the substrate surface absent traces, conductive pads, or other device structures). The electrically non-conductive reflective layer, or any other suitable material adapted to facilitate reflection of light generated by the LED chips 104 can be utilized to increase the overall light output of the light emitter device 200. In some aspects, the reflective material or layer outside of the conductive traces 204 can be disposed on at least 25% or more of the surface of substrate 210 and at a height equal to or lower, or higher than a height of the conductive traces 204 and pads 206, 208. The reflective material can be applied in one step as one layer if desired and can in some aspects also cover at least a portion of the conductive traces without covering the LED chip(s). Furthermore, in some aspects, the conductive traces 204, conductive pads 206, 208, and other metal components of the light emitter device 200 can be coated with a reflective Ag layer for increasing light reflection. An additional reflective layer, such as a second solder mask layer, can be deposited to cover the reflective Ag layer. The additional solder mask layer reduces Ag corrosion due to phosphorus, light absorption due to metals, and increase light reflection.

FIG. 3B illustrates a top perspective view of the light emitter device 200 according to aspects of the disclosure herein. Light emitter device 200 can for example have eight LED chips 104 connected in series via conductive traces and pads. In addition, the conductive traces and pads can be coated with a reflective Ag layer 212 for increasing light reflection.

FIG. 3C illustrates another top perspective view of the light emitter device 200 according to aspects of the disclosure herein. As depicted in FIG. 3C, the light emitter device 200 can have a plurality of direct attach LED chips 104 connected in series by conductive traces 204. In some aspects, the conductive traces 204 can be narrower in width than the LED chip 104. For example and without limitation, the LED chip 104 can be a CREE DA 500 chip with a width of 500 μm, and the conductive trace 204 can have a width from approximately 50 to 100 μm. A narrow conductive trace means that there is less metal on substrate 210, which improves and increases light output and brightness from light emitter device 200 by reducing light absorption by the metal.

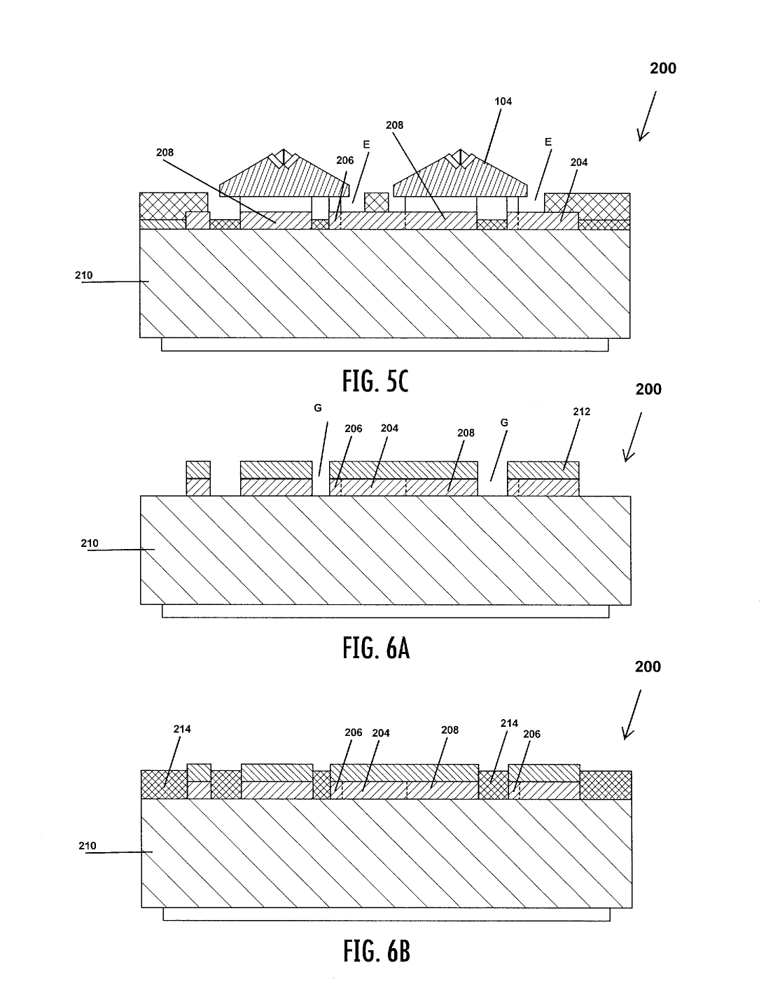

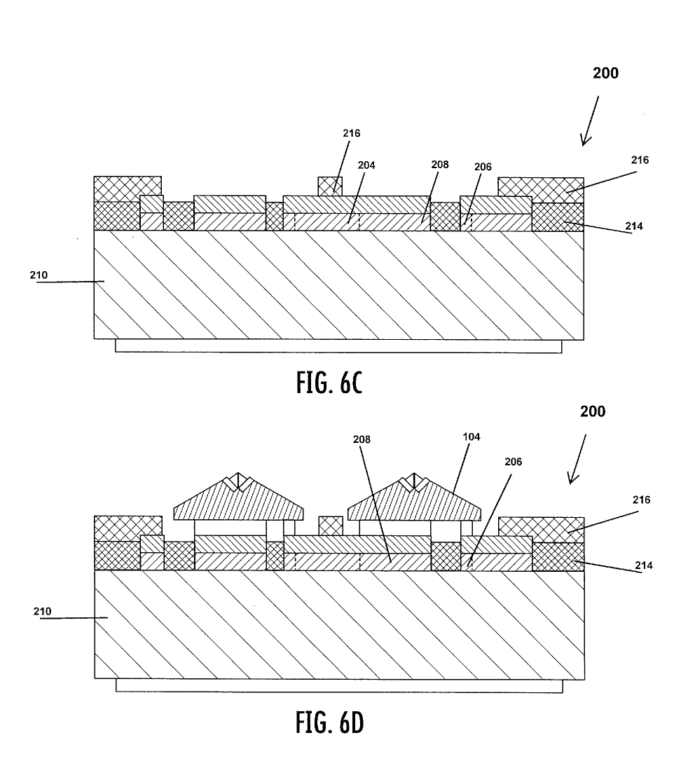

FIG. 3D illustrates another top perspective view of the light emitter device 200 according to aspects of the disclosure herein. As illustrated in FIG. 3D, the light emitter device 200 can have a layer of electrically non-conductive reflective material 214 over exposed regions of the substrate 210 (e.g. regions absent conductive traces, pads, or other device structures). For example, electrically non-conductive reflective material such solder mask can be used to cover the regions between the conductive traces and pads, including the gap G regions (FIGS. 5A to 6D). In some aspects, the electrically non-conductive reflective layer 214 can have a height that is lower than or equal to the height of the conductive traces or pads, as shown in FIG. 3D. Alternatively, in some aspects, the electrically non-conductive reflective layer 214 can have a height that's higher than the height of the conductive traces or pads. As shown in FIG. 3E, the conductive traces and pads can be covered underneath the electrically non-conductive reflective layer 214.

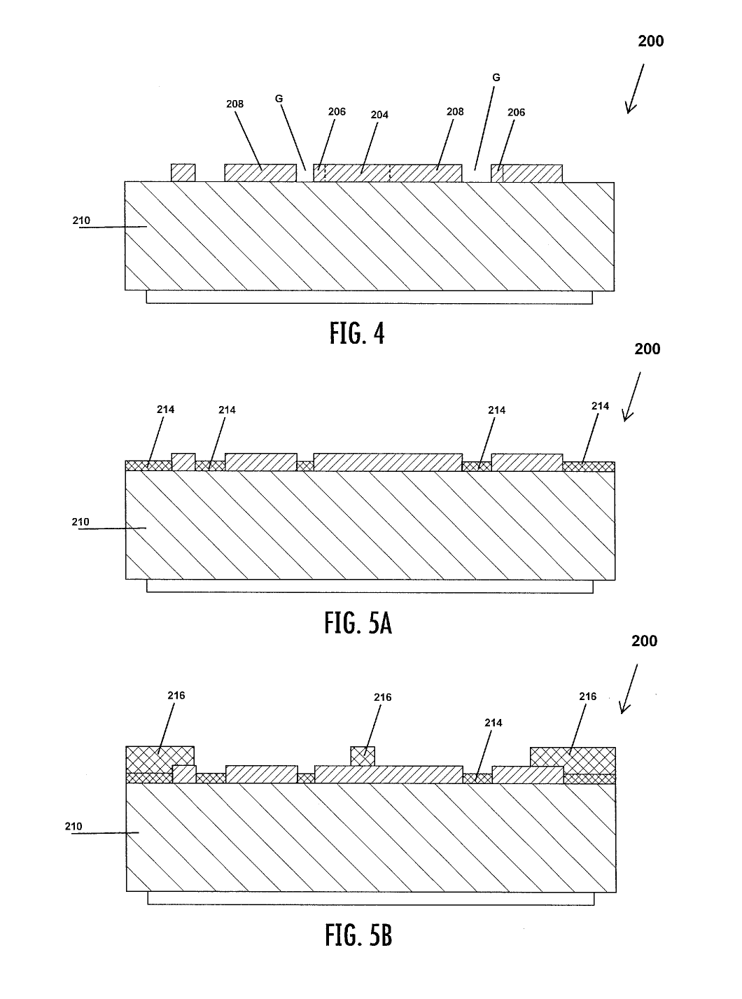

FIGS. 4 to 6D illustrate various cross section views of light emitter device 200 according to aspects of the disclosure herein. It should be noted that the cross section views including two LED chips 104 are provided to explain and provide an example of the subject matter and not as a limitation. As depicted in FIG. 4, conductive traces 204 and pads 206, 208 can be disposed over a substrate 210. The substrate 210 can comprise any suitable mounting substrate, for example, a semiconductor wafer, a printed circuit board (PCB), a metal core printed circuit board (MCPCB), a ceramic substrate, an external circuit, or any other suitable substrate over which lighting devices such as LEDs may mount and/or attach. In some aspects, it may be preferred to utilize aluminum nitride (AlN) or aluminum oxide (Al2O3) substrates for their high isolation voltages and excellent heat dissipating capabilities. Conductive traces 204 and pads 206, 208 can comprise copper (Cu) deposited using known techniques such as plating, and separated by gap, generally designated G, by preventing deposition or removing of Cu in that area. In some aspects, the gap G can physically separate the pads 206 and 208 so the pads are electrically isolated from each other. Gap G can extend down to the top surface of substrate 210 thereby electrically isolating conductive pads 206 and 208.

Referring to FIG. 5A, light emitter device 200 can include a layer of reflective material, such as for example a solder mask layer 214, disposed over exposed regions of the substrate surface including the gap G regions (e.g. part of the substrate surface absent traces, conductive pads, or other device structures). The reflective layer 214, or any other suitable material adapted to facilitate reflection of light generated by the LED chips 104 can be utilized to increase the overall light output of the light emitter device 200. In some aspects, the reflective material or layer outside of the conductive traces 204 can be disposed on over at least 25% or more of the surface of substrate 210 and at a height lower, or higher than that of the conductive traces 204 and pads 206, 208. As noted herein, the reflective material can be applied in one step as one layer if desired and can in some aspects also cover at least a portion of the conductive traces without covering the LED chip(s).

FIG. 5B depicts a cross-section view of the light emitter device 200 including an additional, or second, reflective layer 216 disposed over the first solder mask layer 214. In some aspects, the additional reflective layer 216 can comprise a solder mask layer disposed over the substrate except where the LED chips 104 will be placed. The additional reflective layer 216 can cover less surface area than the first reflective layer, but can cover previously exposed conductive trace 204 and pads 206, 208 including traces 204 between two LED chips 104. This coverage improves light output of the light emitter device 200 by reducing light absorption by the metals. As illustrated in FIG. 5C, LED chips 104 can be placed on conductive pads 206 and 208. In some aspects, a gap E can be present between LED chip 104 and the second solder layer 216 due to fabrication limitations. For example, the gap E can be approximately 100 μm wide as a result of the photolithography alignment.

FIG. 6A to 6D further illustrates another embodiment of the light emitter device 200. FIG. 6A depicts a reflective layer 212 disposed over the conductive traces 204 and pads 206, 208. In some aspects, the reflective layer 212 can comprise a Ag layer to increase light reflection from device 200. A gap G can physically separate the silver reflective layer 212 and the underneath conductive pads 206 and 108. Gap G can extend down to the top of the surface of substrate 210 thereby electrically isolating the silver layer on top of the conductive pads 206 and 208. In some embodiments, as illustrated in FIG. 6B, a layer of reflective material, such as a solder mask, can be disposed over exposed regions of the substrate surface including the gap G regions (e.g. part of the substrate surface absent traces, conductive pads, or other device structures). The reflective material, or any other suitable material adapted to facilitate reflection of light generated by the LED chips can be utilize to increase the overall light output of the light emitter device 200. In some aspects, the solder mask material or layer outside of the conductive traces 204 can be disposed on at least 25% or more of the surface of substrate 210 and at a height equal to or lower, or higher than a height of the conductive traces 204 and pads 206, 208.

FIG. 6C depicts a cross section view of the light emitter device 200 including an additional, or second, reflective layer 216 disposed over the first solder mask layer 214. In some aspects, the additional reflective layer 216 can comprise a solder mask layer disposed over the substrate except where the LED chips 104 will be placed. The additional reflective layer 216 can cover less surface area than the first reflective layer, but can cover exposed conductive trace 204 and pads 206, 208 including traces 204 between two LED chips 104. This coverage improves light output of the light emitter device 200 by reducing light absorption by the metals. As illustrated in FIG. 6D, LED chips 104 can then be placed on conductive pads 206 and 208.

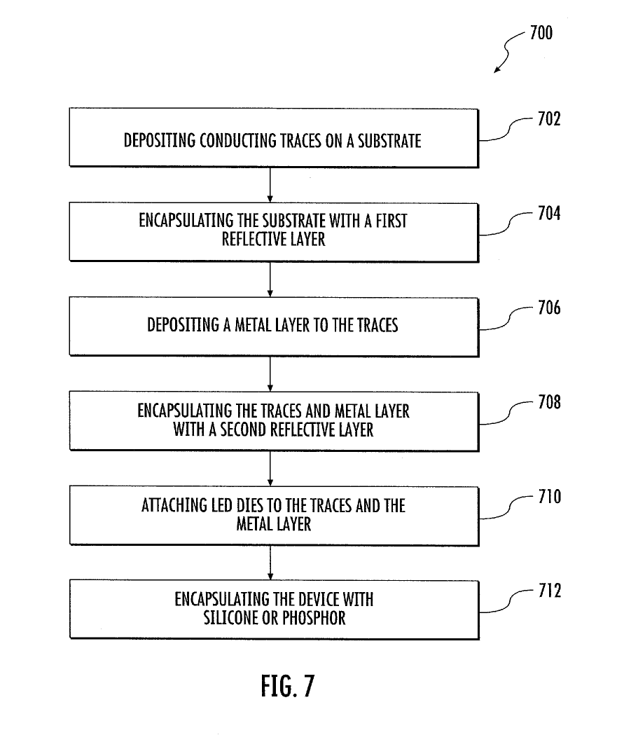

FIG. 7 is a flow chart illustrating an exemplary method, generally designated 700, for providing a light emitter device according to aspects of the disclosure herein. As depicted in FIG. 7, in block 702, conductive traces and pads can be deposited over a substrate. In some aspects, conductive traces and pads can comprise copper (Cu) deposited using known techniques such as plating. In one aspect, a titanium adhesion layer and copper seed layer can be sequentially sputtered onto substrate, then Cu, such as approximately 75 μm of Cu, can be plated onto the Cu seed layer. The resulting Cu layer being deposited can be patterned using standard lithographic processes.

In block 704, a reflective layer of electrically non-conductive material, such as solder mask, may be disposed over the exposed regions of the substrate surface (e.g. part of the substrate surface absent traces, conductive pads, or other device structures). The reflective layer, or any other suitable material adapted to facilitate reflection of light generated by the LED chips, can be utilized to increase the overall light output of the light emitter device. In some aspects, the solder mask layer can be disposed on at least 25% or more of the substrate's surface and at a height equal to or lower than, or higher than a height of the conductive traces and pads. A layer of metal, such as silver, can be deposited over the conductive traces and pads to enhance light reflection from the light emitter device as indicated in block 706.

In some aspects, as indicated in block 708, an additional or second reflective layer can be disposed over the first reflective layer that can also be a solder mask layer. For example, the additional reflective layer can comprise a solder mask layer disposed over the substrate except where the LED chips will be placed. The additional reflective layer can cover less surface area than the first reflective layer, but would cover previously exposed conductive trace and pads, including traces between two LED chips. This coverage improves light output of the light emitter device by reducing light absorption by the metals. LED chips can then be mounted to the conductive pads as indicated in block 710.

Alternatively, in some aspects, LED chips can be mounted onto the conductive pads as indicated in block 710 prior to disposing the second reflective layer (block 708). For example, LED chips can be encapsulated with a layer of photoresist configured to preventing the second reflection material from falling onto the chips. The second reflective layer can then be disposed according to the pattern defined by the photoresist. It should be noted that the sequence of the method presented herein is provided to explain the subject matter and not as a limitation.

In some aspects, as indicated in block 712, the light emitter device may be encapsulated with silicone or phosphor to enhance the overall light output from the device.

Light emitter devices and methods provided in accordance with the disclosure herein have increased light output and can, for example, have a brightness of 2% or more compared with conventional devices that have traces that are not as small between the LED chips as those disclosed herein. In some aspects, an increase of from approximately 2% to 6% in light output is achieved by devices with characteristics disclosed herein for the device including even a single reflective layer. In some aspects, the device is configured to emit light at approximately 80 lumens per watt or more. Light emitter devices and methods provided herein can be used in warm white, neutral white, or cool white lighting applications, including devices encapsulated with silicone or phosphor.

Embodiments as disclosed herein can provide one or more of the following beneficial technical effects: reduced production costs; reduced processing time; improved manufacturability; improved brightness; and improved light extraction, among others.

While the devices and methods have been described herein in reference to specific aspects, features, and illustrative embodiments, it will be appreciated that the utility of the subject matter is not thus limited, but rather extends to and encompasses numerous other variations, modifications and alternative embodiments, as will suggest themselves to those of ordinary skill in the field of the present subject matter, based on the disclosure herein. Various combinations and sub-combinations of the structures and features described herein are contemplated and will be apparent to a skilled person having knowledge of this disclosure. Any of the various features and elements as disclosed herein may be combined with one or more other disclosed features and elements unless indicated to the contrary herein. Correspondingly, the subject matter as hereinafter claimed is intended to be broadly construed and interpreted, as including all such variations, modifications and alternative embodiments, within its scope and including equivalents of the claims.

What is claimed is:

1. A light emitter device comprising:
a substrate;
one or more direct attach light emitting diode (LED) chip disposed over the substrate;
at least one electrically conductive trace electrically connected to the LED chip; and
a reflective and electrically non-conductive material disposed on a surface of the substrate and wherein the reflective material outside of the conductive trace covers at least 25% or more of the surface of the substrate.

2. The light emitter device according to claim 1, wherein a width of the conductive trace is 30% or less of a width of the LED chip.

3. The light emitter device according to claim 1, wherein a width of the conductive trace is less than 100 μm.

4. The light emitter device according to claim 1, wherein the device is configured to emit light at approximately 80 lumens per watt or more.

5. The light emitter device according to claim 1, wherein the substrate comprises at least one of: a semiconductor wafer, a printed circuit board (PCB), a metal core printed circuit board (MCPCB), a ceramic substrate, or an external circuit.

6. The light emitter device according to claim 1, wherein the direct attach LED chip comprises cathode and anode conductive pads.

7. The light emitter device according to claim 6, comprising at least two or more LED chips disposed over the substrate and wherein a cathode conductive pad of a first LED chip is electrically coupled to an anode conductive pad of a second LED chip via the at least one conductive trace.

8. The light emitter device according to claim 6, wherein a combined surface area of the cathode conductive pad and the anode conductive pad is less than a surface area of the LED chip.

9. The light emitter device according to claim 6, wherein the cathode conductive pad and the anode conductive pad are electrically isolated by a gap.

10. The light emitter device according to claim 6, wherein the conductive trace is disposed in a position lower than the cathode and anode conductive pads.

11. The light emitter device according to claim 1, comprising a reflective layer disposed over at least a portion of the conductive trace.

12. The light emitter device according to claim 1, wherein the reflective layer comprises a first solder mask layer.

13. The light emitter device according to claim 12, further comprising a second reflective layer covering less than 100% of the first solder mask layer.

14. The light emitter device according to claim 13, wherein the second reflective layer also covers at least a portion of the conductive trace.

15. The light emitter device according to claim 1, wherein at least two or more conductive traces are provided over the substrate.

16. The light emitter device according to claim 1, comprising a plurality of additional LED chips electrically connected in series.

17. The light emitter device according to claim 1, further comprising at least one layer of metal disposed over the conductive trace.

18. A method for providing a light emitter device, the method comprising:
providing a substrate with a surface;
providing at least one electrically conductive trace over the surface of the substrate;
providing at least one or more light emitting diode (LED) chip over the surface of the substrate; and
disposing a layer of non-conductive and reflective material over the surface of the substrate without covering the conductive trace wherein the layer of reflective material outside of the conductive trace covers at least 25% or more of the surface of the substrate.

19. The method according to claim 18, wherein providing a substrate comprises providing a ceramic substrate, a metallic substrate, a metal core printed circuit board, a flexible substrate, a semiconductor wafer, or a printed circuit board.

20. The method according to claim 18, comprising disposing a cathode conductive pad and an anode conductive pad over the surface of the substrate.

21. The method according to claim 20, wherein disposing the cathode conductive pad and the anode conductive pad comprises forming a gap to electrically isolate the cathode conductive pad and the anode conductive pad.

22. The method according to claim 18, further comprising disposing at least one layer of metal over the conductive trace.

23. The method according to claim 22, further comprising disposing a layer of reflective material over the layer of metal.

24. The method according to claim 18, wherein a width of the conductive trace is 30% or less of a width of the LED chip.

25. The method according to claim 18, wherein a width of the conductive trace is less than 100 μm.

26. The method according to claim 18, wherein the reflective layer comprises a first solder mask layer.

27. The method according to claim 26, further comprising a second reflective layer covering less than 100% of the first solder mask layer.

28. The method according to claim 27, wherein the second reflective layer also covers at least a portion of the conductive trace.

29. The method according to claim 18, wherein the device is configured to emit light at approximately 80 lumens per watt or more.
